(19) United States
(12) Patent Application Publication
(10) Pub. No.: US 2014/0021961 A1
(43) Pub. Date: Jan. 23, 2014

(54) ELECTRIC LEAKAGE DETECTING APPARATUS

(71) Applicant: KEIHIN CORPORATION, Tokyo (JP)

(72) Inventors: Takeshi YAMADA, Tokyo (JP); Hidefumi ABE, Sendai-shi (JP)

(21) Appl. No.: 13/937,897

(22) Filed: Jul. 9, 2013

(30) Foreign Application Priority Data
Jul. 18, 2012 (JP) 2012-159699

(51) Int. Cl. G01R 31/02

(52) U.S. Cl. CPC G01R 31/025
USPC 324/503

(57) ABSTRACT

An electric leakage detecting apparatus, in an electric leakage detecting apparatus which is insulated from a chassis ground and detects electric leakages of a battery, is provided with: a voltage dividing circuit that divides an output voltage of the battery; an electric leakage determining circuit provided at a rear stage of the voltage dividing circuit, that determines the presence of an electric leakage based on a voltage detected by a circuit that respectively connects to a positive electrode side insulation resistance or a negative electrode side insulation resistance of the battery; and a dark current inhibit circuit in which a switch and a resistance are connected in parallel, that is inserted between at least either one of wiring that connects a positive terminal of the battery and the voltage dividing circuit, and wiring that connects a negative terminal of the battery and the voltage dividing circuit.

### CROSS-REFERENCE TO RELATED APPLICATION

Priority is claimed on Japanese Patent Application No. 2012-159699, filed Jul. 18, 2012, the content of which is incorporated herein by reference.

### BACKGROUND

1. Field of the Invention

The present invention relates to an electric leakage detecting apparatus.

2. Description of Related Art

As is well known, vehicles such as electric vehicles and hybrid vehicles are equipped with a motor, which becomes the source of power, and a high voltage and large capacity battery that supplies electric power to the motor. The high voltage battery is one configured by serially connecting a plurality of battery cells comprising lithium ion batteries or hydrogen nickel batteries, or the like.

Such high voltage batteries for driving a motor are insulated from the chassis ground for safety. Therefore, it is very important to monitor the insulated state (or in other words, to detect electric leakages) between the high voltage battery and the chassis ground. Japanese Unexamined Patent Application, First Publication No. 2011-102788 discloses a technique for monitoring the insulated state between a high voltage battery and a chassis ground by using the flying capacitor method.

### SUMMARY

In the technique described in Japanese Unexamined Patent Application, First Publication No. 2011-102788, high voltage resistance circuit components become necessary the more the output voltage of the battery becomes a high voltage, and there is a problem in that the apparatus costs increase. Furthermore, with the battery becoming a high voltage, degradation of the battery may proceed due to the flowing of a large dark current.

Aspects of the present invention take into consideration the above circumstances, with an object of providing an electric leakage detecting apparatus that is able to inhibit the degradation of a battery due to the dark current, while keeping an increase in apparatus costs to a minimum.

The aspects of the present invention employ the following configuration in order to solve the above problems.

(1) An electric leakage detecting apparatus of one aspect of the present invention, in an electric leakage detecting apparatus which is insulated from a chassis ground and detects electric leakages of a battery, is provided with: a voltage dividing circuit that divides an output voltage of the battery; an electric leakage determining circuit provided at a rear stage of the voltage dividing circuit, that determines the presence of an electric leakage based on a voltage detected by a circuit that respectively connects to a positive electrode side insulation resistance or a negative electrode side insulation resistance of the battery; and a dark current inhibit circuit in which a switch and a resistance are connected in parallel, that is inserted between at least either one of a wiring that connects a positive terminal of the battery and the voltage dividing circuit, and a wiring that connects a negative terminal of the battery and the voltage dividing circuit.

(2) In the aspect of (1) above, the electric leakage determining circuit may selectively switch a path of electric current that flows to a capacitor which is insulated from the chassis ground, between: a first path that is not connected to the positive electrode side insulation resistance and the negative electrode side insulation resistance of the battery, a second path that is connected to the positive electrode side insulation resistance, and a third path that is connected to the negative electrode side insulation resistance, and determine the presence of an electric leakage based on a voltage charged to the capacitor by the first path, the second path, and the third path, respectively.

(3) In the aspect of (1) or (2) above, resistances that constitute the voltage dividing circuit may all have the same resistance value.

(4) In the aspect of (2) or (3) above, the electric leakage determining circuit may, at the time a voltage charged to the capacitor is detected, disconnect an electrical connection between its circuit and the voltage dividing circuit.

(5) In the aspect of any one from (2) to (4) above, the switch of the dark current inhibit circuit may become an ON state during the time period wherein one among the first path, the second path, and the third path is selected as the path in which the electric current flows to the capacitor, and the capacitor is being charged, and may become an OFF state during other time periods thereof.

According to the above aspects of the present invention, the voltage dividing circuit that divides the output voltage of the battery is provided at a front stage of the electric leakage determining circuit. Therefore, the withstanding voltage of the circuit components that constitute the electric leakage determining circuit can be lowered (or in other words, the electric leakage determining circuit can be constituted by inexpensive circuit components). In the present invention, component costs are required to the extent that the voltage dividing circuit and the dark current inhibit circuit are provided. However, as mentioned above, since the electric leakage determining circuit can be constituted by inexpensive circuit components, the increase in the apparatus costs in total can be kept to a minimum.

Furthermore, according to the above aspects of the present invention, the dark current inhibit circuit in which the switch and the resistance are connected in parallel, is inserted between at least either the wiring that connects the positive terminal of the battery and the voltage dividing circuit, and the wiring that connects the negative terminal of the battery and the voltage dividing circuit. Therefore generation of the dark current can be inhibited.

That is to say, according to the aspects of the present invention, it becomes possible to inhibit the degradation of the battery due to the dark current, while keeping the increase in apparatus costs to a minimum.

### BRIEF DESCRIPTION OF THE DRAWINGS

FIG. 1 is a schematic block diagram of an electric leakage detecting apparatus 1 of an embodiment according to the present invention.

FIG. 2 is a timing chart showing the temporal changes of the ON/OFF state of switches SW1 to SW6 provided in the electric leakage detecting apparatus 1.

FIG. 3 is a drawing showing the path (first path) of the electric current flowing to a flying capacitor C at the time the switches SW1, SW2, SW3, and SW4 are in an ON state.

FIG. 4A is a drawing showing the path (second path) of the electric current flowing to the flying capacitor C at the time the switches SW1, SW2, SW4, and SW5 are in an ON state, and the switches SW3 and SW6 are in an OFF state.

FIG. 4B is a drawing showing the path (third path) of the electric current flowing to the flying capacitor C at the time the switches SW1, SW2, SW3, and SW6 are in an ON state, and the switches SW4 and SW5 are in an OFF state.

### DESCRIPTION OF THE EMBODIMENT

Herein, an embodiment of the present invention is described with reference to the drawings.

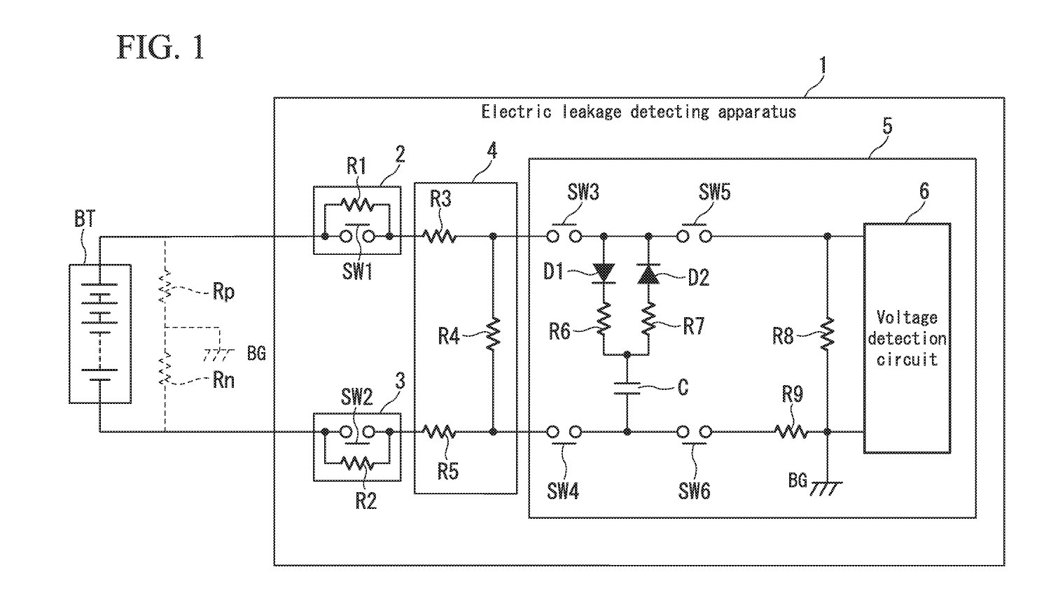

FIG. 1 is a schematic block diagram of an electric leakage detecting apparatus 1 according to the present embodiment. The electric leakage detecting apparatus 1 is one that detects electric leakages of a high voltage battery BT (a battery with a rated voltage of 900 V for example) for driving a motor that is insulated from a chassis ground BG, and is provided with a first dark current inhibit circuit 2, a second dark current inhibit circuit 3, a voltage dividing circuit 4, and an electric leakage determining circuit 5.

The first dark current inhibit circuit 2 is constituted by a switch SW1 with one end connected to the positive terminal of the high voltage battery BT and the other end connected to the voltage dividing circuit 4 (specifically a resistance R3 mentioned below), and a resistance R1 connected in parallel to the switch SW1. The second dark current inhibit circuit 3 is constituted by a switch SW2 with one end connected to the negative terminal of the high voltage battery BT and the other end connected to the voltage dividing circuit 4 (specifically a resistance R5 mentioned below), and a resistance R2 connected in parallel to the switch SW2.

In this manner, in the electric leakage detecting apparatus 1 of the present embodiment, dark current inhibit circuits comprising a switch and a resistance connected in parallel are inserted between both the wiring that connects the positive terminal of the high voltage battery BT and the voltage dividing circuit 4 (resistance R3), and the wiring that connects the negative terminal of the high voltage battery BT and the voltage dividing circuit 4 (resistance R5). The ON/OFF state of the switch SW1 and the switch SW2 is controlled by a voltage detection circuit 6 provided in the electric leakage determining circuit 5 mentioned below.

The voltage dividing circuit 4 is connected to the high voltage battery BT via the first dark current inhibit circuit 2 and the second dark current inhibit circuit 3, and is one that divides the output voltage of the high voltage battery BT of for example 900 V, to approximately 600 V, for example, and is constituted by the three resistances R3, R4, and R5.

One end of the resistance R3 is connected to the first dark current inhibit circuit 2, and the other end is connected to one end of the resistance R4 and the electric leakage determining circuit 5 (specifically a switch SW3 mentioned below). One end of the resistance R5 is connected to the second dark current inhibit circuit 3, and the other end is connected to the other end of the resistance R4 and the electric leakage determining circuit 5 (specifically a switch SW4 mentioned below). One end of the resistance R4 is connected to the other end of the resistance R3, and the other end is connected to the other end of the resistance R5. The resistances R3, R4, and R5 that constitute the voltage dividing circuit 4 all have the same resistance value.

The electric leakage determining circuit 5 is provided at a rear stage of the voltage dividing circuit 4, and selectively switches the path of the electric current that flows to a capacitor insulated from the chassis ground BG, between: a first path that is not connected to the positive electrode side insulation resistance Rp and the negative electrode side insulation resistance Rn of the high voltage battery BT, a second path that is connected to the positive electrode side insulation resistance Rp, and a third path that is connected to the negative electrode side insulation resistance Rn. Then it determines the presence of an electric leakage based on the voltage charged to the capacitor by the first path, the second path, and the third path, respectively.

Such an electric leakage determining circuit 5 is constituted by a flying capacitor C that corresponds to the capacitor mentioned above, four switches SW3, SW4, SW5, and SW6, four resistances R6, R7, R8, and R9, two diodes D1 and D2, and a voltage detection circuit 6.

One end of the switch SW3 is connected to the voltage dividing circuit 4 (the other end of the resistance R3), and the other end is connected to one end of the switch SW5, the anode terminal of the diode D1, and the cathode terminal of the diode D2. One end of the switch SW4 is connected to the voltage dividing circuit 4 (the other end of the resistance R5), and the other end is connected to one end of the switch SW6, and one end of the flying capacitor C.

One end of the flying capacitor C is connected to the other end of the switch SW4 and one end of the switch SW6, and the other end is connected to one end of the resistance R6 and one end of the resistance R7. One end of the resistance R6 is connected to the other end of the flying capacitor C, and the other end is connected to the cathode terminal of the diode D1. One end of the resistance R7 is connected to the other end of the flying capacitor C, and the other end is connected to the anode terminal of the diode D2.

The anode terminal of the diode D1 is connected to the other end of the switch SW3, one end of the switch SW5, and the cathode terminal of the diode D2, and the cathode terminal is connected to the other end of the resistance R6. The anode terminal of the diode D2 is connected to the other end of the resistance R7, and the cathode terminal is connected to the other end of the switch SW3, one end of the switch SW5, and the anode terminal of the diode D1.

One end of the switch SW5 is connected to the other end of the switch SW3, the anode terminal of the diode D1, and the cathode terminal of the diode D2, and the other end is connected to one end of the resistance R8 and the voltage detection circuit 6. One end of the switch SW6 is connected to the other end of the switch SW4 and one end of the flying capacitor C, and the other end is connected to one end of the resistance R9.

One end of the resistance R8 is connected to the other end of the switch SW5 and the voltage detection circuit 6, and the other end is connected to the other end of the resistance R9, the voltage detection circuit 6, and the chassis ground BG. One end of the resistance R9 is connected to the other end of the switch SW6, and the other end is connected to the other end of the resistance R8, the voltage detection circuit 6, and the chassis ground BG.

The voltage detection circuit 6 is for example a digital processor that executes various processes according to a program of a microcomputer, and it controls the ON/OFF state of the switches SW1 to SW6, to thereby have: a function of selectively switching the path of the electric current that flows to the flying capacitor C between the first path mentioned above that is not connected to the positive electrode side insulation resistance Rp and the negative electrode side insulation resistance Rn, the second path that is connected to the positive electrode side insulation resistance Rp, and the third path that is connected to the negative electrode side insulation resistance Rn; and a function of detecting the voltage charged to the flying capacitor C by the first path, the second path, and the third path, respectively, and determining the presence of an electrical leakage based on the detection result thereof.

Hereunder is a description of the operation of the electric leakage detecting apparatus 1 constituted as described above.

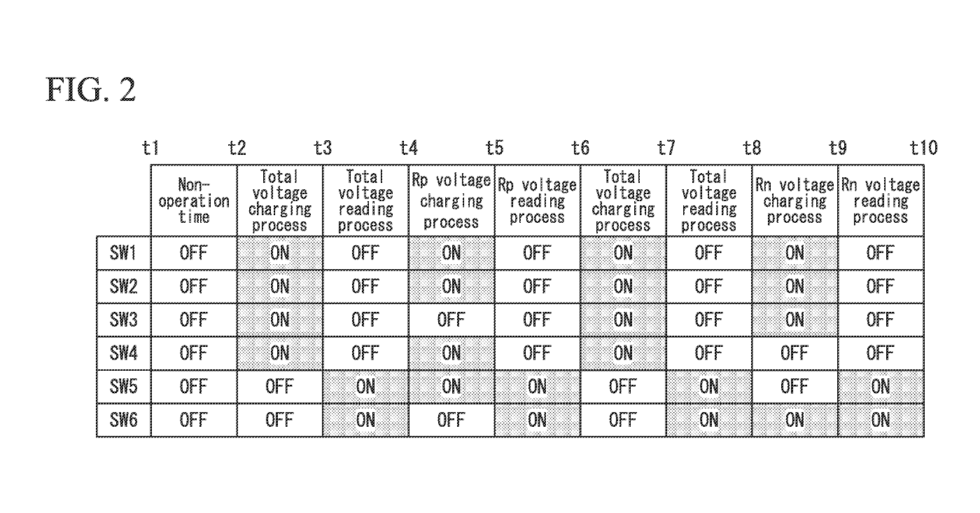

FIG. 2 is a timing chart showing the temporal changes of the ON/OFF state of the switches SW1 to SW6 provided in the electric leakage detecting apparatus 1. As shown in FIG. 2, at the time of non-operation, that is to say, during the period when the electric leakage detection operation is not executed (the period of time t1 to t2 in the figure), the voltage detection circuit 6 controls all of the switches SW1 to SW6 to the OFF state.

When all of the switches SW1 to SW6 become the OFF state, an electric current (dark current) flows along the path of the positive terminal of the high voltage battery BT→the resistance R1→the resistance R3→the resistance R4→the resistance R5→the resistance R2→the negative terminal of the high voltage battery BT. However the dark current can be inhibited by setting the resistance values of the resistance R1 of the first dark current inhibit circuit 2 and the resistance R2 of the second dark current inhibit circuit 3 to a large value.

Assuming that the electric leakage detection operation is started from the time t2 in the figure, the voltage detection circuit 6 firstly executes a total voltage charging process in the period from time t2 to t3. Specifically, the voltage detection circuit 6 controls the switches SW1, SW2, SW3, and SW4 to the ON state within the period from time t2 to t3, to thereby switch the path of the electric current that flows to the flying capacitor C to the first path that is not connected to the positive electrode side insulation resistance Rp and the negative electrode side insulation resistance Rn.

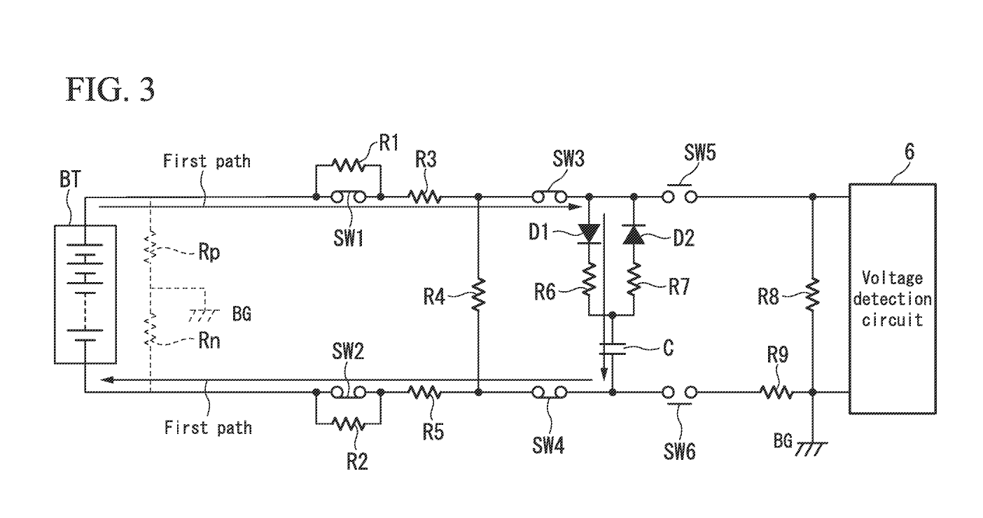

When the switches SW1, SW2, SW3, and SW4 become the ON state, then as shown in FIG. 3, an electric current flows along the path (that is to say, the first path) of the positive terminal of the high voltage battery BT—the switch SW1→the resistance R3→the switch SW3→the diode D1→the resistance R6→the flying capacitor C→the switch SW4→the resistance R5→the switch SW2→the negative terminal of the high voltage battery BT.

In such a manner, in a case where the switches SW1, SW2, SW3, and SW4 are made the ON state, the combined resistance R of the first path in which the electric current flows is represented by formula (1) below. Furthermore, the voltage Vc (that is to say, the inter-terminal voltage of the flying capacitor C) charged to the flying capacitor C is represented by formula (2) below. In formula (2) below, Vb is the output voltage of the high voltage battery BT, and Ton1 is the charging time (Ton1=t3−t2) of the flying capacitor C. Hereunder, the voltage Vc charged to the flying capacitor C at the time of execution of the total voltage charging process in the manner mentioned above is referred to as the total voltage.

$$\begin{matrix}R = \frac{R 3}{( R 4 + R 5 )} + R 6 & ( 1 ) \\ Vc = Vb \times \frac{R 4}{( R 3 + R 4 + R 5 )} \times \{ 1 - EXP ( \frac{- Ton 1}{R \times C} ) \} & ( 2 )\end{matrix}$$

Next, the voltage detection circuit 6 executes a total voltage reading process in the period from time t3 to t4 in FIG. 2. Specifically, the voltage detection circuit 6, within the period from time t3 to t4, controls the switches SW1, SW2, SW3, and SW4 to the OFF state, and controls the switches SW5 and SW6 to the ON state, to thereby detect the inter-terminal voltage of the flying capacitor C, that is to say, the total voltage Vc (converted to a digital value and read in), and stores the detection result (digital value of the total voltage Vc) thereof in an internal memory.

In practice, the total voltage Vc is divided by the resistances R7, R8, and R9, and read into the voltage detection circuit 6 as the inter-terminal voltage of the resistance R8. Consequently, the voltage detection circuit 6 converts the read in inter-terminal voltage of the resistance R8, into the inter-terminal voltage of the flying capacitor C, that is to say, the total voltage Vc, based on the resistance values of the resistances R7, R8, and R9.

Next, the voltage detection circuit 6 executes a positive electrode side insulation resistance voltage charging process in the period from time t4 to t5 in FIG. 2. Specifically, the voltage detection circuit 6, within the period from time t4 to t5, controls the switches SW1, SW2, SW4, and SW5 to the ON state, and controls the switches SW3 and SW6 to the OFF state, to thereby switch the path of the electric current that flows to the flying capacitor C to the second path that is connected to the positive electrode side insulation resistance Rp.

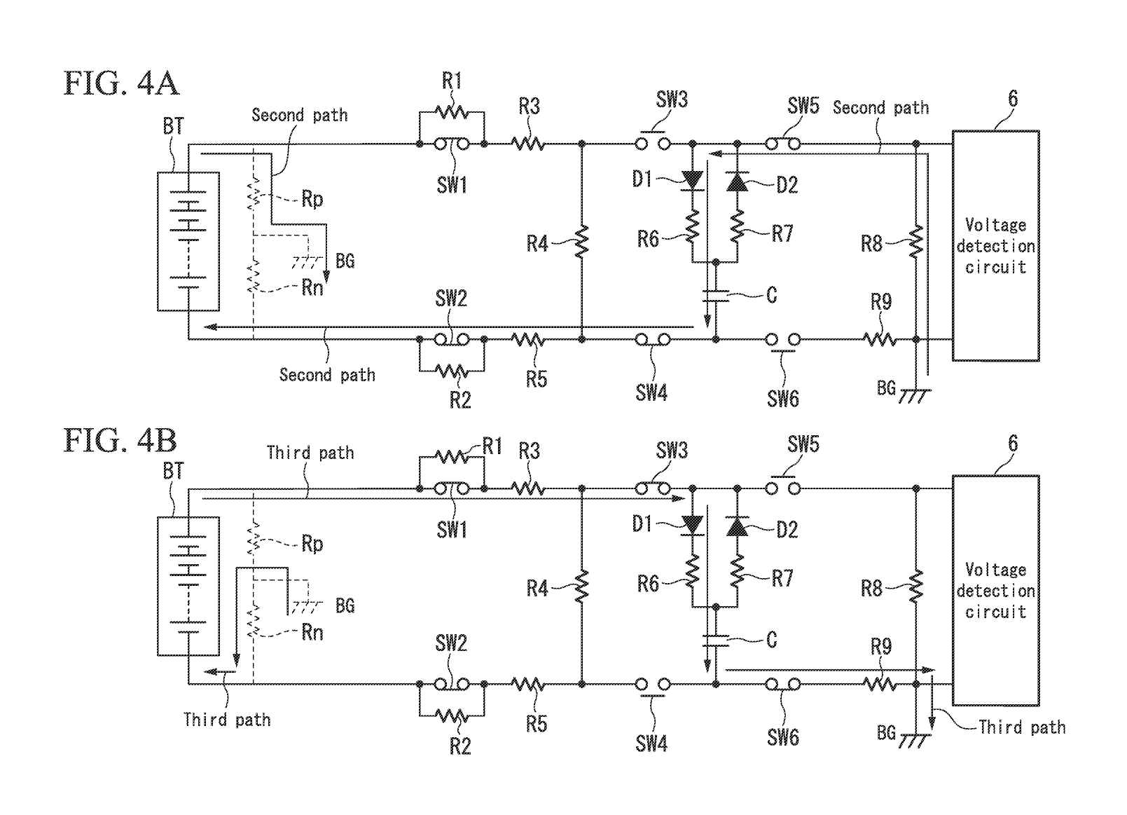

When the switches SW1, SW2, SW4, and SW5 become the ON state, and the switches SW3 and SW6 become the OFF state, then as shown in FIG. 4A, an electric current flows along the path (that is to say, the second path) of the positive terminal of the high voltage battery BT→the positive electrode side insulation resistance Rp→the chassis ground BG→the resistance R8→the switch SW5→the diode D1→the resistance R6→the flying capacitor C→the switch SW4→the resistance R5→the switch SW2→the negative terminal of the high voltage battery BT.

In such a manner, in a case where the switches SW1, SW2, SW4, and SW5 are made the ON state, and the switches SW3 and SW6 are made the OFF state, the combined resistance R(+) of the second path in which the electric current flows is represented by formula (3) below. Furthermore, the voltage Vcp charged to the flying capacitor C is represented by formula (4) below. In formula (4) below, Ton2 is the charging time (Ton2 =t5−t4) of the flying capacitor C. Hereunder, the voltage Vcp charged to the flying capacitor C at the time of execution of the positive electrode side insulation resistance voltage charging process in the manner mentioned above is referred to as the positive electrode side insulation resistance voltage.

$$\begin{matrix}R ( + ) = \frac{( R 3 + R 4 )}{R 5} + R 6 + \frac{Rp}{Rn} & ( 3 ) \\ Vcp = Vb \times ( \frac{Rn}{Rp + Rn} - \frac{R 5}{R 3 + R 4 + R 5} ) \times \{ 1 - EXP ( \frac{- Ton 2}{R ( + ) \times C} ) \} & ( 4 )\end{matrix}$$

Next, the voltage detection circuit 6 executes a positive electrode side insulation resistance voltage reading process in the period from time t5 to t6 in FIG. 2. Specifically, the voltage detection circuit 6, within the period from time t5 to t6, controls the switches SW1, SW2, SW3, and SW4 to the OFF state, and controls the switches SW5 and SW6 to the ON state, to thereby detect the inter-terminal voltage of the flying capacitor C, that is to say, the positive electrode side insulation resistance voltage Vcp (converted to a digital value and read in), and stores the detection result (digital value of the positive electrode side insulation resistance voltage Vcp) thereof in an internal memory.

In the same manner as mentioned above, in practice, the positive electrode side insulation resistance voltage Vcp is divided by the resistances R7, R8, and R9, and read into the voltage detection circuit 6 as the inter-terminal voltage of the resistance R8. Consequently, the voltage detection circuit 6 converts the read in inter-terminal voltage of the resistance R8, into the positive electrode side insulation resistance voltage Vcp, based on the resistance values of the resistances R7, R8, and R9.

Next, the voltage detection circuit 6 executes a total voltage charging process again in the period from time t6 to t7 in the figure. That is to say, the voltage detection circuit 6, within the period from time t6 to t7, controls the switches SW1, SW2, SW3, and SW4 to the ON state, to thereby switch the path of the electric current that flows to the flying capacitor C to the first path. Consequently, the total voltage Vc represented by formula (2) mentioned above is charged to the flying capacitor C.

Next, the voltage detection circuit 6 executes a total voltage reading process in the period from time t7 to t8 in FIG. 2. That is to say, the voltage detection circuit 6, within the period from time t7 to t8, controls the switches SW1, SW2, SW3, and SW4 to the OFF state, and controls the switches SW5 and SW6 to the ON state, to thereby detect the inter-terminal voltage of the flying capacitor C, that is to say, the total voltage Vc (converted to a digital value and read in), and stores the detection result (digital value of the total voltage Vc) thereof in an internal memory.

Next, the voltage detection circuit 6 executes a negative electrode side insulation resistance voltage charging process in the period from time t8 to t9 in FIG. 2. Specifically, the voltage detection circuit 6, within the period from time t8 to t9, controls the switches SW1, SW2, SW3, and SW6 to the ON state, and controls the switches SW4 and SW5 to the OFF state, to thereby switch the path of the electric current that flows to the flying capacitor C to the third path that is connected to the negative electrode side insulation resistance Rn.

When the switches SW1, SW2, SW3, and SW6 become the ON state, and the switches SW4 and SW5 become the OFF state, then as shown in FIG. 4B, an electric current flows along the path (that is to say, the third path) of; the positive terminal of the high voltage battery BT→the switch SW1→the resistance R3→the switch SW3→the diode D1→the resistance R6→the flying capacitor C→the switch SW6→the resistance R9→the chassis ground BG→the negative electrode side insulation resistance Rn→the negative terminal of the high voltage battery BT.

In such a manner, in a case where the switches SW1, SW2, SW3, and SW6 are made the ON state, and the switches SW4 and SW5 are made the OFF state, the combined resistance R(−) of the third path in which the electric current flows is represented by formula (5) below. Furthermore, the voltage Vcn charged to the flying capacitor C is represented by formula (6) below. In formula (6) below, Ton2 is the charging time (Ton2 =t9−t8) of the flying capacitor C. Hereunder, the voltage Vcn charged to the flying capacitor C at the time of execution of the negative electrode side insulation resistance voltage charging process in the manner mentioned above is referred to as the negative electrode side insulation resistance voltage.

$$\begin{matrix}R ( - ) = \frac{( R 4 + R 5 )}{R 3} + R 6 + \frac{Rp}{Rn} & ( 5 ) \\ Vcn = Vb \times ( \frac{R 4 + R 5}{R 3 + R 4 + R 5} - \frac{Rn}{Rp + Rn} ) \times \{ 1 - EXP ( \frac{- Ton 2}{R ( - ) \times C} ) \} & ( 6 )\end{matrix}$$

Next, the voltage detection circuit 6 executes a negative electrode side insulation resistance voltage reading process in the period from time t9 to t10 in FIG. 2. Specifically, the voltage detection circuit 6, within the period from time t9 to t10, controls the switches SW1, SW2, SW3, and SW4 to the OFF state, and controls the switches SW5 and SW6 to the ON state, to thereby detect the inter-terminal voltage of the flying capacitor C, that is to say, the negative electrode side insulation resistance voltage Vcn (converted to a digital value and read in), and stores the detection result (digital value of the negative electrode side insulation resistance voltage Vcn) thereof in an internal memory.

In the same manner as mentioned above, in practice, the negative electrode side insulation resistance voltage Vcn is divided by the resistances R7, R8, and R9, and read into the voltage detection circuit 6 as the inter-terminal voltage of the resistance R8. Therefore, the voltage detection circuit 6 converts the read in inter-terminal voltage of the resistance R8, into the negative electrode side insulation resistance voltage Vcn, based on the resistance values of the resistances R7, R8, and R9.

The voltage detection circuit 6 calculates the insulation resistance value based on the total voltage Vc, the positive electrode side insulation resistance voltage Vcp, and the negative electrode side insulation resistance voltage Vcn, obtained by the processes executed in the periods from time t2 to t10 as mentioned above, and determines that an electrical leakage has occurred in a case where the calculated insulation resistance value thereof is less than a threshold value. When R2=R4, R(+)=R(−)=R. Therefore Vcn+Vcp is represented by formula (7) below, and the insulation resistance value is represented by formula (8) below.

$$\begin{matrix}Vcn + Vcp = Vb \times \frac{R 4}{R 3 + R 4 + R 5} \times \{ 1 - EXP ( \frac{- Ton 2}{R \times C} ) \} & ( 7 ) \\ \begin{matrix}Ratio of insulation \\ resistance values\end{matrix} = \frac{Rp}{Rn} = \frac{- Ton 2}{C} \times \frac{1}{LN \{ 1 - \frac{R 3 + R 4 + R 5}{R 3 \times Vb} \times ( Vcn + Vcp ) \}} - \frac{R 3 + R 4}{R 2} - R 6 & ( 8 )\end{matrix}$$

In the above manner, according to the present embodiment, the voltage dividing circuit 4 that divides the output voltage of the high voltage battery BT, is provided at a front stage of the electric leakage determining circuit 5. Therefore, the withstanding voltage of the circuit components that constitute the electric leakage determining circuit 5 can be lowered (or in other words, the electric leakage determining circuit 5 can be constituted by inexpensive circuit components). In the present embodiment, component costs are required to the extent that the voltage dividing circuit 4 and the dark current inhibit circuits 2 and 3 are provided. However, as mentioned above, since the electric leakage determining circuit 5 can be constituted by inexpensive circuit components, the increase in the apparatus costs in total can be kept to a minimum.

Furthermore, according to the present embodiment, the dark current inhibit circuits 2 and 3 in which the switches and the resistances are connected in parallel, are inserted between, at least, both the wiring that connects the positive terminal of the high voltage battery BT and the voltage dividing circuit 4, and the wiring that connects the negative terminal of the high voltage battery BT and the voltage dividing circuit 4. Therefore generation of the dark current can be inhibited. That is to say, according to the electric leakage detecting apparatus 1 of the present embodiment, it becomes possible to inhibit the degradation of the battery due to the dark current, while keeping the increase in apparatus costs to a minimum.

Further, the electric leakage detection accuracy decreases if the resistance values of the resistances R3, R4, and R5 that constitute the voltage dividing circuit 4 become too small. However, by making the resistance values of the resistances R3, R4, and R5 that constitute the voltage dividing circuit 4 all the same in the manner of the present embodiment, the electric leakage detection accuracy can be maintained.

Moreover, at the time the voltage charged to the flying capacitor C is detected, the switches SW1, SW2, SW3, and SW4 are made the OFF state, the switches SW5 and SW6 are made the ON state, and the electrical connection between the electric leakage determining circuit 5 and the voltage dividing circuit 4 is disconnected. As a result, the application of a voltage to the switches SW5 and SW6 that exceeds the withstanding voltage can be avoided.

The present invention is in no way limited by the embodiment mentioned above. For example, in the embodiment mentioned above, a case in which the dark current inhibit circuits 2 and 3 are inserted between both the wiring that connects the positive terminal of the high voltage battery BT and the voltage dividing circuit 4, and the wiring that connects the negative terminal of the high voltage battery BT and the voltage dividing circuit 4 is exemplified. However, even if either one of the dark current inhibit circuits 2 and 3 is inserted between just one of the wirings, their effect is exerted.

Furthermore, in the embodiment mentioned above, the electric leakage determining circuit 5 of a so-called flying capacitor method that selectively switches the path of the electric current that flows to the flying capacitor C between; the first path that is not connected to the positive electrode side insulation resistance Rp and the negative electrode side insulation resistance Rn, the second path that is connected to the positive electrode side insulation resistance Rp, and the third path that is connected to the negative electrode side insulation resistance Rn, and determines the presence of an electric leakage based on the voltage charged to the flying capacitor C at the first path, the second path, and the third path, respectively, is exemplified. The present invention is in no way limited to this, and an electric leakage determining circuit (for example an electric leakage determining circuit of a resistance dividing method) that determines the presence of an electric leakage based on the voltage detected in a path that is respectively connected to the positive electrode side insulation resistance Rp or the negative electrode side insulation resistance Rn of the high voltage battery BT may be employed.

What is claimed is:

1. An electric leakage detecting apparatus, in an electric leakage detecting apparatus which is insulated from a chassis ground and detects electric leakages of a battery, provided with:
a voltage dividing circuit that divides an output voltage of the battery;
an electric leakage determining circuit provided at a rear stage of the voltage dividing circuit, that determines the presence of an electric leakage based on a voltage detected by a circuit that respectively connects to a positive electrode side insulation resistance or a negative electrode side insulation resistance of the battery; and
a dark current inhibit circuit in which a switch and a resistance are connected in parallel, that is inserted between at least either one of a wiring that connects a positive terminal of the battery and the voltage dividing circuit, and a wiring that connects a negative terminal of the battery and the voltage dividing circuit.

2. An electric leakage detecting apparatus according to claim 1, wherein the electric leakage determining circuit selectively switches a path of electric current that flows to a capacitor which is insulated from the chassis ground, between: a first path that is not connected to the positive electrode side insulation resistance and the negative electrode side insulation resistance of the battery, a second path that is connected to the positive electrode side insulation resistance, and a third path that is connected to the negative electrode side insulation resistance, and determines the presence of an electric leakage based on a voltage charged to the capacitor by the first path, the second path, and the third path, respectively.

3. An electric leakage detecting apparatus according to claim 1, wherein resistances that constitute the voltage dividing circuit all have the same resistance value.

4. An electric leakage detecting apparatus according to claim 2, wherein the electric leakage determining circuit, at the time a voltage charged to the capacitor is detected, disconnects an electrical connection between its circuit and the voltage dividing circuit.

5. An electric leakage detecting apparatus according to claim 2, wherein the switch of the dark current inhibit circuit becomes an ON state during the time period wherein one among the first path, the second path, and the third path is selected as the path in which the electric current flows to the capacitor, and the capacitor is being charged, and becomes an OFF state during other time periods thereof.
